(19) United States
(12) Patent Application Publication
(10) Pub. No.: US 2024/0170268 A1
(43) Pub. Date: May 23, 2024

(54) PROCESS CHAMBER WITH IMPROVED PROCESS FEEDBACK

(71) Applicant: Applied Materials, Inc., Santa Clara, CA (US)

(72) Inventors: Tobin KAUFMAN-OSBORN, Sunnyvale, CA (US); Hugo RIVERA, Santa Clara, CA (US); Wei LIU, San Jose, CA (US)

(21) Appl. No.: 18/487,432

(22) Filed: Oct. 16, 2023

Related U.S. Application Data
(60) Provisional application No. 63/424,538, filed on Nov. 11, 2022.

(51) Int. Cl. H01J 37/32

(52) U.S. Cl. CPC H01J 37/3299; H01J 37/3211; H01J 2237/327

(57) ABSTRACT

A plasma processing system is provided including a processing chamber, one or more optical emission spectroscopy (OES) systems, and a controller. The processing chamber includes a chamber body enclosing a processing volume. The chamber body includes one or more windows. The processing chamber further includes a substrate support in the processing volume, a coil positioned over the substrate support, and one or more actuators configured to move the coil. Each OES system is optically coupled to one of the one or more windows and each OES system having an optical component configured to perform OES measurements on a portion of the processing volume. The controller is configured to adjust a position of the one or more actuators to move the coil based on the OES measurements.

### RELATED APPLICATIONS

This application claims benefit of and priority to U.S. Provisional Patent Application No. 63/424,538, filed Nov. 11, 2022, the entire contents of which are incorporated herein by reference.

### BACKGROUND

Embodiments of the present disclosure generally relate to a process chamber and related methods for improving the uniformity of a process performed on a substrate (e.g., a semiconductor substrate).

### Description of the Related Art

Product uniformity is strived for in processes performed on substrates, such as semiconductor processes. This uniformity includes uniformity for the process results achieved for different substrates and uniformity for the process results achieved across different portions of a given substrate. As the dimensions of the features formed on substrates become smaller and smaller, the challenges relating to process uniformity continue to increase.

Accordingly, there is a continuing need for improved methods and related equipment to achieve product uniformity on processes performed on substrates, such as semiconductor processes.

### SUMMARY

In one embodiment, a plasma processing system is provided including a processing chamber, one or more optical emission spectroscopy (OES) systems, and a controller. The processing chamber includes a chamber body enclosing a processing volume. The chamber body includes one or more windows. The processing chamber further includes a substrate support in the processing volume, a coil positioned over the substrate support, and one or more actuators configured to move the coil. Each OES system is optically coupled to one of the one or more windows and each OES system having an optical component configured to perform OES measurements on a portion of the processing volume. The controller is configured to adjust a position of the one or more actuators to move the coil based on the OES measurements.

In another embodiment, a method of performing a process in a process chamber is provided. The method includes: positioning a substrate on a substrate support in a processing volume of a process chamber, the process chamber having a chamber body enclosing the processing volume; providing one or more gases to the processing volume of the process chamber; providing RF power to a coil disposed over the substrate support to generate a plasma of the one or more gases provided to the processing volume; performing optical emission spectroscopy (OES) measurements of two or more locations of the processing volume during the generation of the plasma using one or more OES systems, each OES system having an optical component configured to view a portion of the processing volume; and moving the coil during the generation of the plasma based on the OES measurements.

In another embodiment, a method of performing a process in a process chamber is provided. The method includes: performing optical emission spectroscopy (OES) measurements of a plasma in a processing volume of a process chamber using four or more OES systems, each OES system having an optical component configured to view a portion of the processing volume, wherein the optical component of each OES system has an orientation that is offset from about ten degrees to about sixty degrees in a horizontal plane relative to a horizontal radii extending from a center of a substrate support in the processing volume to the corresponding optical component; and adjusting an output to modify a spatial uniformity of the plasma based on the OES measurements.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a side cross-sectional view of a processing system, according to one embodiment.

FIG. 1B is a top view of components in the processing system of FIG. 1A for controlling an inductively coupled plasma in the process chamber, according to one embodiment.

FIG. 2 is a top view of components in an alternative processing system for controlling an inductively coupled plasma in the process chamber, according to one embodiment.

FIG. 3A is a top view of components in an alternative processing system for controlling an inductively coupled plasma in the process chamber, according to one embodiment.

FIG. 3B is a top view of components in an alternative processing system for controlling an inductively coupled plasma in the process chamber, according to one embodiment.

FIG. 4 is a top view of components in an alternative processing system for controlling an inductively coupled plasma in the process chamber, according to one embodiment.

FIG. 5 is a process flow diagram of a method for generating a plasma in the process chamber of FIG. 1A using any of the processing systems described above, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to process chambers and related methods for improving the uniformity of plasma processes performed on substrates (e.g., semiconductor substrates). Some improvements are achieved by using feedback from one or more optical emission spectroscopy (OES) systems during a plasma process to make adjustments in real-time based on the OES feedback. In one embodiment, the adjustment made based on the OES feedback is adjusting a tilt and/or a position of one or more coils used to form an inductive plasma in the process chamber. Although the following mainly describes using OES feedback to improve an inductively coupled plasma (ICP) process, the benefits of this disclosure are not limited to ICP processes and can be applied to other plasma processes, such as capacitively coupled plasma processes or processes using a remote plasma source.

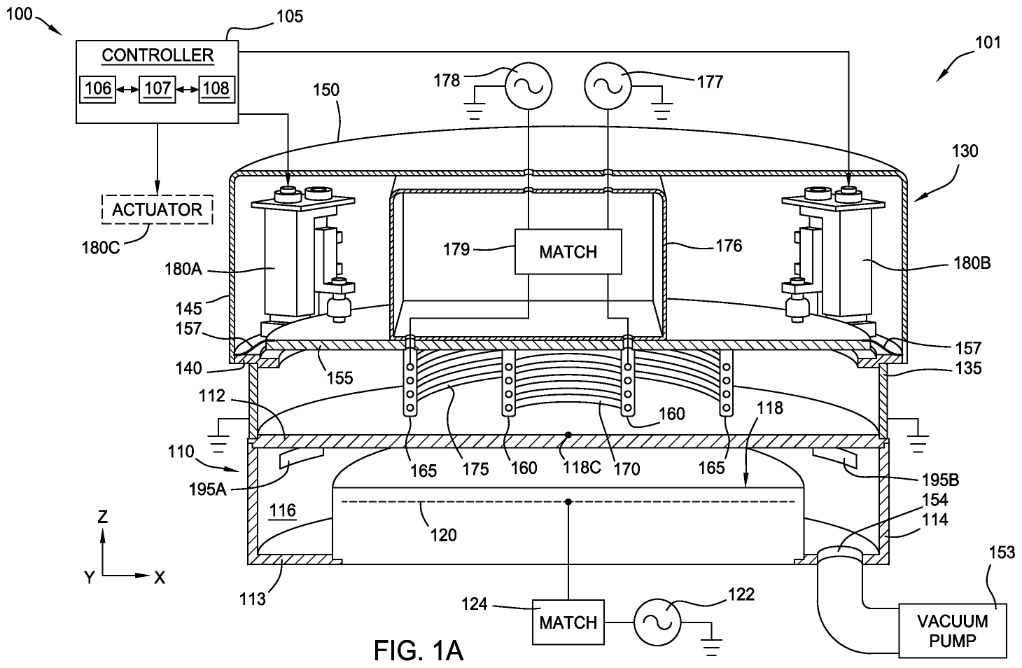

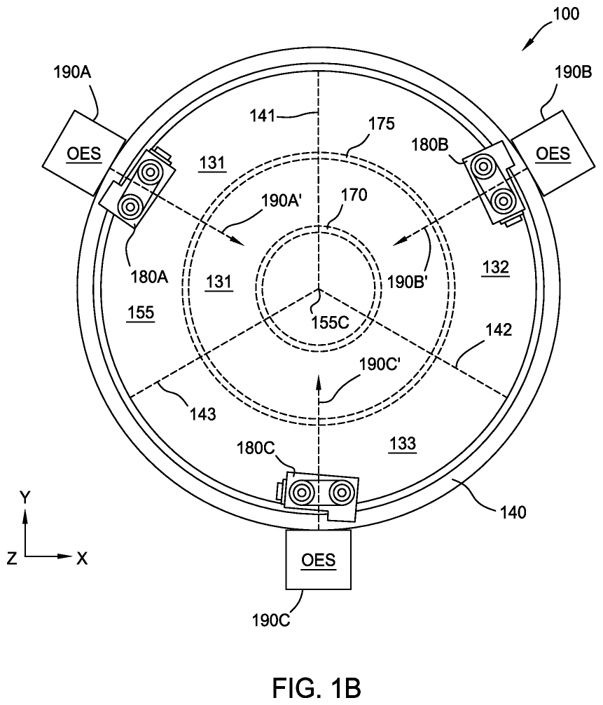

FIG. 1A is a side cross-sectional view of a processing system 100, according to one embodiment. The processing system 100 includes a process chamber 101. FIG. 1B is a top view of components in the processing system 100 for controlling an inductively coupled plasma in the process chamber 101, according to one embodiment.

The processing system 100 can be used to form an inductively coupled plasma in the process chamber 101 for processes including but not limited to a deposition process, an etch process, a cleaning process, or a decoupled plasma process (e.g., a decoupled plasma nitridation process).

The process chamber 101 includes a chamber body 110. The chamber body 110 includes a top 112, a base 113, and one or more side walls 114 connecting the base 113 with the top 112. The chamber body 110 encloses a processing volume 116. The process chamber 101 includes a substrate support 118 disposed inside the processing volume 116. The substrate support 118 includes a bias electrode 120. A substrate (not shown) can be positioned on the substrate support 118 during processing, for example during a plasma process, such as a decoupled plasma nitridation.

Process gases can be provided to the processing volume 116 through one or more gas lines (not shown) that can extend through a portion of the one or more side walls 114 or from a showerhead (not shown) positioned over the substrate support 118. The process chamber 101 includes an exhaust port 154 coupled to a vacuum pump 153 to remove gases from the processing volume 116 and to maintain a specified pressure in the processing volume 116 during a process.

The process chamber 100 can include an inner coil 170 and an outer coil 175 positioned over the top 112 of the chamber body 110. The process chamber 101 can include one or more side walls 135 positioned around the coils 170, 175. The one or more side walls 135 can be connected to electrical ground. The one or more side walls 135 can extend upward from the top 112 of the chamber body 110.

RF power can be applied to the inner coil 170 and the outer coil 175 to generate an inductively coupled plasma in the processing volume 116. The processing system 100 includes a first RF power supply 177, a second RF power supply 178, and a matching circuit 179. The matching circuit 179 can be positioned in an enclosure 176. The first RF power supply 177 can be coupled to the inner coil 170 through the matching circuit 179. The second RF power supply 178 can be coupled to the outer coil 175 through the matching circuit 179. With the two RF power supplies 177, 178, the RF power provided to the inner coil 170 can be independent of the RF power provided to the outer coil 175, so that the plasma generated over a central portion of a substrate can be modified relative to the plasma generated over an edge region of the substrate. Although the power sources 177, 178 are described as RF power sources, power sources having other frequencies can also be used to generate a plasma. Furthermore, in some embodiments, one power supply can supply power (e.g., RF power) to both the inner coil 170 and the outer coil 175. In some of these embodiments including one power supply, the proportion of the total power from the power supply provided to the inner coil 170 relative to the outer coil 175 can be adjusted to independently, for example by the match circuit, control the plasma generated under the inner coil 170 relative to the plasma generated under the outer coil 175.

The process chamber 101 includes a shoulder ring 140 positioned on the one or more sidewalls 135. The process chamber 101 includes a support plate 155 positioned over the coils 170, 175. The support plate 155 can be positioned on or over the shoulder ring 140 in a floating arrangement, so that the support plate 155 can move relative to one or more side walls 135. As described in further detail below, moving portions of the support plate 155 moves portions of the coils 170, 175 closer to or further from the substrate support 118, which can be used to modify the plasma generated across different portions of the processing volume 116. The inner coil 170 can be mounted to the support plate 155 using brackets 160. The outer coil 175 can be mounted to the support plate 155 using brackets 165.

The process chamber 101 can further include three actuators 180A, 180B, 180C (see also FIG. 1B) that are coupled to the support plate 155. The actuators 180A-180C can be positioned in a symmetrical arrangement (e.g., 120 degrees apart) around the support plate 155. The third actuator 180C is not visible in the side cross-sectional view of FIG. 1A and is shown as a dashed box connected to the controller 105 to indicate this lack of visibility. FIG. 1B shows the position of the third actuator 180C. Each actuator 180 is configured to vertically move a portion of the support plate 155 enabling the support plate 155 and coils 170, 175 to be raised, lowered, or tilted. Each actuator 180 can be a linear actuator, such as servo. Used herein, moving a coil, such as the coils 170, 175, can refer to tilting and/or raising or lowering of the coils.

The process chamber 101 further includes a lid assembly 130 positioned over the support plate 155. The lid assembly 130 can be positioned around the shoulder ring 140. The lid assembly 130 includes one or more side walls 145 and a top 150. The lid assembly 130 can include a plurality of ground straps 157 connected between the support plate 155 and the shoulder ring 140 that enable the support plate 155 to remain grounded when the support plate 155 is moved.

The processing system 100 can further include a bias power source 122 that is coupled through a matching circuit 124 to the bias electrode 120 in the substrate support 118. The bias power source 122 can provide an RF bias, a DC bias, or both.

The one or more side walls 114 of the chamber body 110 can further include a first window 195A and a second window 195B to enable optical emission spectroscopy (OES) measurements to be performed on the plasma generated in the processing volume 116. The first window 195A can be aligned with an angular position of the first actuator 180A relative to a center 118C of the substrate support 118. The second window 195B can be aligned with an angular position of the second actuator 180B relative to a center 118C of the substrate support 118. A third window 195C (not shown) can be aligned with an angular position of the third actuator 180C (see FIG. 1B). Aligning the windows 195 with the actuators 180 can allow OES measurements to be performed on the plasma in regions of the processing volume 116 closest to the corresponding actuator 180. In other embodiments, the windows and corresponding OES systems are not aligned with the actuators that can be used to modify the plasma.

The processing system 100 further includes an OES system 190 optically coupled to each window 195. Three OES systems 190A, 190B, 190C are shown in FIG. 1B. Each OES system 190 can provide wavelength data based on the components (e.g., atoms, molecules, ions, radicals) emitting radiation in the plasma. The wavelength data can include peaks indicating the presence of different components in the plasma. Each peak is associated with a particular component in the plasma. The intensity of the peaks is related to the concentration of the corresponding component in the plasma. For a uniform plasma, the OES systems 190A, 190B, 190C will record peaks having the same or substantially similar intensities. For example, if NH₃ is a component provided to the processing volume 116 during a plasma process in the process chamber 101, each OES system 190 will record peaks having a same or substantially similar intensity for the one or more peaks corresponding to NH₃ when the plasma is uniform across different portions of the processing volume. Each OES system 190 can include one or more components (e.g., one or more spectrometers) for separating the radiation received by the OES system 190 by wavelength as well as one or more sensors (e.g., photodetectors, such as charge coupled devices) to determine the intensity of radiation received at the different wavelengths.

Each OES system 190A-C can include an optical component (e.g., an optical fiber for capturing radiation, such as light, emitted during the plasma) having an orientation 190A′-190C′ that is aligned with a radii extending from the center 118C of the substrate support 118 (see FIG. 1A). Although the substrate support 118 is not shown in FIG. 1B, a center 155C of the support plate 155 in the XY-plane can be aligned with the center 118C of the substrate support 118 (i.e., 118C and 155 have the same XY coordinates and are only separated in the Z-direction). With these orientations 190A′-190C′ and the positions of OES systems 190 shown in FIG. 1B, each OES system 190 can record measurements for one third or substantially one third of the volume over the substrate support 118 in the processing volume 116 during a plasma process. For example, as shown in FIG. 1B, each OES 190A-C is oriented at a central portion of a sector 131-133. Each sector 131-133 can correspond to a volume of space over the substrate support 118 that includes the volume where the plasma is formed during processing. Each sector 131-133 can have a same size as the other sectors 131-133. The boundaries for the sectors 131-133 in an XY plane can be represented by boundary lines 141-143 that meet at the center 118C of the substrate support 118. In FIG. 1B, each boundary line 141-143 can be oriented 120 degrees from the other boundary lines 141-143.

In some embodiments, the OES systems 190 can each be oriented and focused so that there is little to no overlap between the regions of plasma measured by the other OES systems 190. In some embodiments, the OES systems 190 can be oriented in a horizontal direction. In other embodiments, the OES systems 190 can be oriented downward or upward, for example from about −30 degrees to about +30 degrees, such as from about −15 degrees to about +15 degrees.

Each actuator 180 can move the portion of the support plate 155 that the corresponding actuator 180 is coupled to in response to the OES measurements from the closest OES system 190 or in response to the measurements from two or more of the OES systems 190, for example when a comparison between the measurements from different OES systems 190 is made. For example, if OES system 190C indicates an intensity for a wavelength peak of a given component (e.g., NH₃) is below the corresponding intensity measured by the other OES systems 190A, 190B when the intensities for that wavelength peak measured by the other OES systems 190A, 190B are closer to an intensity setpoint for that component, then the actuator 180C can move the portions of the plate 155 and coils 170, 175 closest to the actuator 180C and OES system 190C further from the substrate support 118. This movement causes a tilt of the coils 170, 175 and a central axis of the coils 170, 175 (e.g., an axis substantially aligned in the Z-direction) to move towards sector 133. Moving these portions of the coils 170, 175 further from the substrate support 118 can raise the intensity of the magnetic field coupled from the coils 170, 175 to sector 133. This increase in the intensity of the magnetic field can raise the intensity for the wavelength peak of the given component (i.e., NH₃) in sector 133 that is measured by OES system 190C, so that a more uniform plasma with intensity measurements closer to specified setpoints can be achieved for each sector 131-133. In some embodiments, a same setpoint is used for each OES system included in a processing system, such as OES systems 190A-190C. In other embodiments, it may be beneficial to offset one or more of the setpoints relative to each other. For example, in some embodiments, a more uniform plasma may be obtained by using setpoints that are offset (e.g., by a few percent) from each other, due to the likelihood that identical plasmas will not generate the exact same measurements by different OES systems in different locations of a plasma chamber.

The processing system 100 can also include a controller 105 for controlling processes performed by the processing system 100. The controller 105 can be any type of controller used in an industrial setting, such as a programmable logic controller (PLC). The controller 105 includes a processor 107, a memory 106, and input/output (I/O) circuits 108. The controller 105 can further include one or more of the following components (not shown), such as one or more power supplies, clocks, communication components (e.g., network interface card), and user interfaces typically found in controllers for semiconductor equipment.

The memory 106 can include non-transitory memory. The non-transitory memory can be used to store the programs and settings described below. The memory 106 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

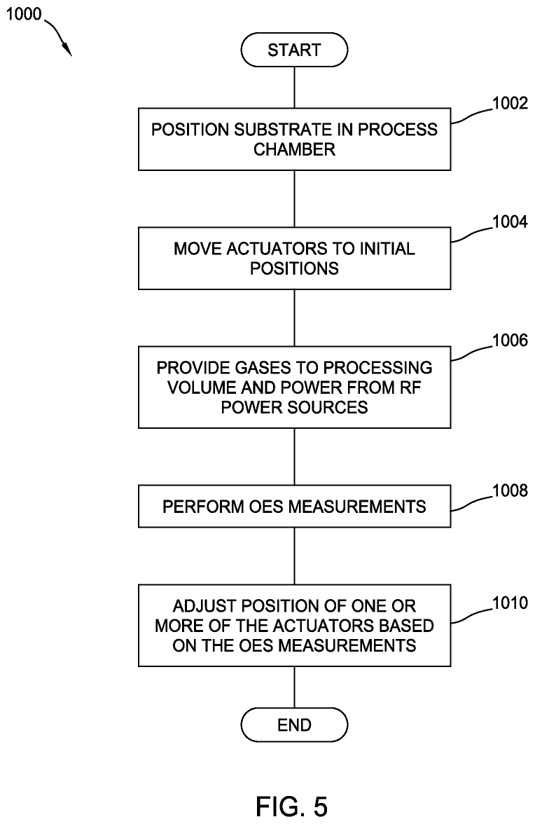

The processor 107 is configured to execute various programs stored in the memory 106, such as a program configured to execute the method 1000 described below in reference to FIG. 5. During execution of these programs, the controller 105 can communicate to I/O devices (e.g., OES systems 190, actuators 180, and power sources 122, 177, 178) through the I/O circuits 108. For example, during execution of these programs and communication through the I/O circuits 108, the controller 105 can control outputs, for example to control the position of the support plate 155 using the actuators 180 and receive information from feedback devices (e.g., OES systems 190) and other inputs (e.g., sensors) in the processing system 100. The memory 106 can further include various operational settings used to control the processing system 100. For example, the settings can include actuator 180 position settings for different types of processes performed in the process chamber 101.

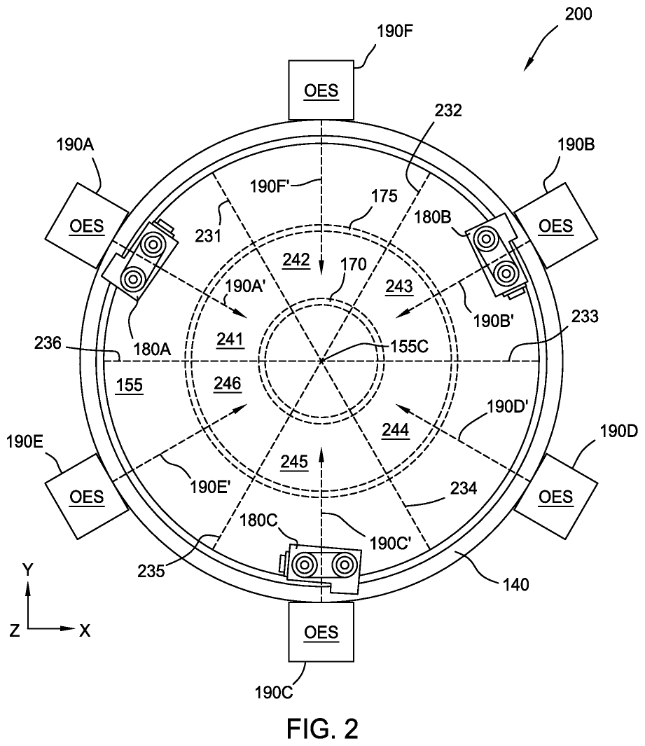

FIG. 2 is a top view of components in a processing system 200 for controlling an inductively coupled plasma in the process chamber 101, according to one embodiment. The processing system 200 is the same as the processing system 100 described above except that the processing system 200 includes three additional OES systems 190D, 190E, and 190F as well as three additional windows (not shown) to allow the three additional OES systems 190D-F to view portions of the plasma over the substrate support 118 during processing. The additional OES systems 190D-190F can each have optical components having corresponding orientations 190D′-190F′ that are aligned with a radii extending from the center 118C of the substrate support 118 (see FIG. 1A) to enable the OES systems 190D-190F to perform OES measurements of different portions of the plasma during processing.

In some embodiments, these additional OES systems 190D-F can allow OES measurements to be performed on smaller portions of the processing volume 116 during a plasma process performed in the process chamber 101, so that additional data on the spatial uniformity of a plasma generated in the processing volume 118 (see FIG. 1A) can be obtained. For example, in the processing system 100 described above (FIGS. 1A and 1B), the three OES systems 190A-C can each be configured to focus on one third of the processing volume 116 over the substrate support 118 while in the processing system 200 the six OES systems 190A-F can each be configured to focus on one sixth of the processing volume 116 over the substrate support 118. FIG. 2 shows each OES system 190A-F focused on a sector 231-236. Each sector 231-236 can correspond to a volume of space over the substrate support 118 that includes the volume where the plasma is formed during processing. Each sector 231-236 can have a same size as the other sectors 231-236. The boundaries for the sectors 231-236 in an XY plane can be represented by boundary lines 241-246 that meet at the center 118C (see FIG. 1A) of the substrate support 118. In FIG. 1B, each boundary line 241-246 can be oriented 60 degrees from a next boundary line 241-246.

With the additional data from the three additional OES systems 190A-C, each OES system 190 has a corresponding opposing OES system 190 located 180 degrees apart. For example, the OES system 190A is disposed in an opposing position relative to the OES system 190D, the OES system 190B is disposed in an opposing position relative to the OES system 190E, and the OES system 190C is disposed in an opposing position relative to the OES system 190F. The opposing OES systems 190 can be oriented and focused so that there is little to no overlap between the regions of plasma measured by the different OES systems 190.

In some embodiments, a given actuator 180 can be controlled by a comparison between measurements from the OES system 190 aligned with the actuator 180 and the measurements from the opposing OES system 190. For example, if OES system 190C indicates an intensity for a wavelength peak for a given component (e.g., NH₃) is below the corresponding intensity measured by the opposing OES system 190F when the intensity of the component measured by the OES system 190F is closer to an intensity setpoint for that component, then the actuator 180C can move the portions of the plate 155 and coils 170, 175 closest to the actuator 180C and OES system 190C further from the substrate support 118. This movement causes a tilt of the coils 170, 175 and a central axis of the coils 170, 175 (e.g., an axis substantially aligned in the Z-direction) to move towards sector 245. Moving these portions of the coils 170, 175 further from the substrate support 118 can raise the intensity of the magnetic field coupled to sector 245, which in turn can raise the intensity for the wavelength peak of the given component (i.e., NH₃) in sector 245 that is measured by OES system 190C, so that a more uniform plasma with intensity measurements closer to specified setpoints can be achieved for each sector 241-246.

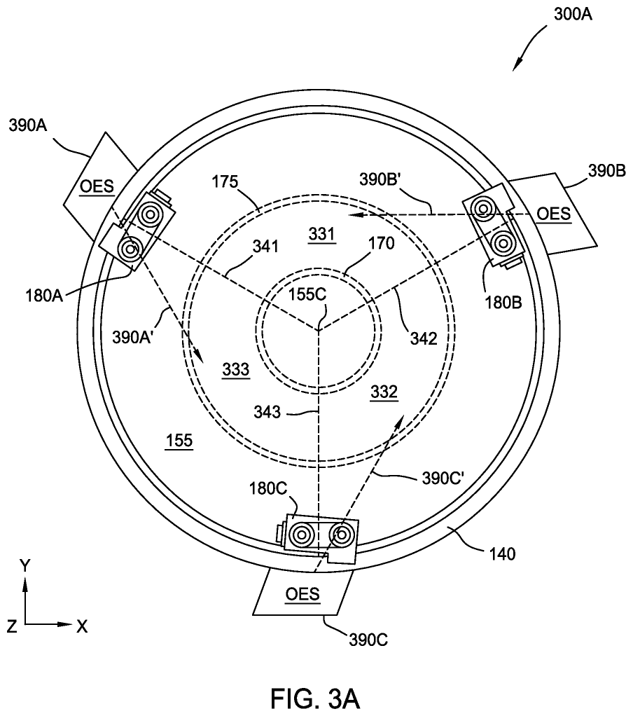

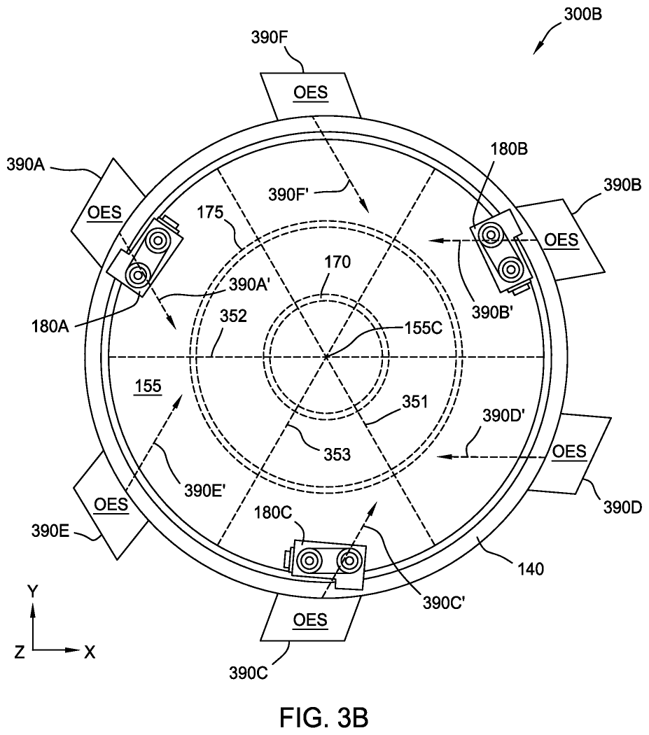

FIG. 3A is a top view of components in a processing system 300A for controlling an inductively coupled plasma in the process chamber 101, according to one embodiment. The processing system 300A is the same as the processing system 100 described above except that the processing system 300A has OES systems 390A, 390B, and 390C with the optical component (e.g., optical fiber for capturing light) pointed in different orientations 390A′-390C′ relative to the OES systems 190A, 190B, 190C shown in FIG. 1B which are pointed in the orientations 190A′-190C′. In the processing system 300A, the orientations 390A′-390C′ of the OES systems 390A-390C are not directed to extend towards the center 118C of the substrate support 118 (see FIG. 1A). Instead, the OES systems 390A-390C are directed to have orientations 390A′-390C′ that extend across a middle region between a center 118C of the substrate support 118 and the outer edge of the substrate support 118. Thus, the orientations 390A′-390C′ are not aligned with a radii extending from the center 118C of the substrate support 118. Instead, the orientations 390A′-390C′ are offset by 30 degrees in a horizontal plane (i.e., XY plane) relative to a radii extending from a center 118C of the substrate support 118 in a horizontal plane. In other embodiments, other orientations can be used, such as orientations offset from about 10 degrees to about 60 degrees in a horizontal plane relative to a radii extending from a center 118C of the substrate support 118 in a horizontal plane. This offset of these orientations 390A′-390C′ (e.g., 30 degrees) can help reduce the likelihood of the OES systems 390A-390C from performing measurements on the same portions of a plasma formed in the process chamber 101. For example, the orientations 390A′-390C′ can be configured to not intersect with each other in the processing volume 116 or in the portion of the processing volume 116 in which the plasma is generated.

In some embodiments, the OES systems 390 can be oriented in a horizontal direction. In other embodiments, the OES systems 390 can be oriented downward or upward, for example from about −30 degrees to about +30 degrees, such as from about −15 degrees to about +15 degrees. The orientations 390D′-390F′ described below in reference to FIG. 3B can have similar orientations to orientations described herein for the orientations 390A′-390C′.

The measurement from each OES system 390A-390C can be configured to perform measurements on a different sector 331-333 in the processing volume 116. Each sector 331-333 can include one third of the processing volume 116 that includes the plasma during a process. The sectors 331-333 can be formed by boundary lines 341-343 extending from the center of the OES systems 190A-190C to the center 118C of the substrate support 118 (see FIG. 1A). The second OES system 390B can be oriented towards a center of the first sector 331. The third OES system 390C can be oriented towards a center of the second sector 332. The first OES system 390A can be oriented towards a center of the third sector 333. Each OES system 390A-390C can also be described as being oriented towards another OES system 390A-390C that is located 120 degrees apart from that OES system. For example, the first OES system 390A is oriented towards the third OES system 390C. The second OES system 390A is oriented towards the first OES system 390A. The third OES system 390C is oriented towards the second OES system 390B.

Furthermore, each orientation 390A′-390C′ is perpendicular to one of the boundary lines 341-343. For example, the orientation 390A′ is perpendicular to boundary line 342, the orientation 390B′ is perpendicular to boundary line 343, and the orientation 390C′ is perpendicular to boundary line 341. This arrangement allows each actuator 180A-180C to control an opposing sector 331-333. For example, actuator 180A can be used to control opposing sector 332 because movement by actuator 180A causes the portion of the coils 170, 175 over sector 332 to tilt in opposite direction relative to the portion of the coils 170, 175 closest to the actuator 180A. In a similar arrangement, actuator 180B can be used to control opposing sector 333, and actuator 180C can be used to control opposing sector 331.

As an example, if OES system 390C indicates an intensity for a wavelength peak of a given component (e.g., NH₃) for sector 332 is below the corresponding intensity measured by the other OES systems 390A, 390B for corresponding sectors 333, 331 when the intensities for that wavelength peak measured by the other OES systems 390A, 390B for sectors 333, 331 are closer to an intensity setpoint for that component, then the actuator 180A can move the portions of the plate 155 and coils 170, 175 closest to the actuator 180A closer to the substrate support 118. This movement by the actuator 180A causes a tilt of the coils 170, 175 and the portions of the coils 170, 175 overlying sector 332 to move further from the substrate support 118, which causes a central axis of the coils 170, 175 (e.g., an axis substantially aligned in the Z-direction) to move towards sector 332. Moving this central axis of the coils 170, 175 towards sector 332 increases the intensity of the magnetic field coupled into sector 332, which in turn increases the intensity of the wavelength peak for the given component (i.e., NH₃) measured by the OES system 390C to result in a more uniform intensity over all of the sectors 331-333.

Although many of the examples above describe the movement of only one actuator 180, this is to simplify the explanation. During operation, two or more of the actuators 180 may move simultaneously. For example, if OES measurements indicate that intensities for a given wavelength peak are each above or each below the intensity setpoint for that wavelength peak, then each actuator 180A-180C can move to address this disparity. The actuators 180A-180C can each activate to move the coils 170, 175 closer to the substrate support 118 if each OES system 390A-390C is measuring intensities for a given wavelength peak that is below the intensity setpoint for that wavelength peak. Furthermore, each actuator can move by a different amount. Also, an actuator 180 can move to counteract tilting caused by movement of another actuator 180.

FIG. 3B is a top view of components in a processing system 300B for controlling an inductively coupled plasma in the process chamber 101, according to one embodiment. The processing system 300B is the same as the processing system 300A described above except that the processing system 300B has three additional OES systems 390D, 390E, and 390F in addition to the OES systems 390A, 390B, 390C included in the processing system 300A. The processing system 300B can further include three additional windows (not shown) to allow the three additional OES systems 390D-F to view portions of the plasma over the substrate support 118 (see FIG. 1A).

The three additional OES systems 390D-390F are directed into the processing volume 116 at corresponding orientations 390D′-390F′. The orientation 390A′ is parallel to the orientation 390F′. The orientation 390B′ is parallel to the orientation 390D′. The orientation 390C′ is parallel to the orientation 390E′. The OES measurements from the OES systems 390 that are parallel to each other can be used to control the plasma in the processing volume 116 (see FIG. 1A).

Each member of an OES system pair can be configured to view a different side of the processing volume 116. For example, the OES systems 390A, 390F can be configured to view opposing sides of diameter boundary line 351. Similarly, the OES systems 390B, 390D can be configured to view opposing sides of diameter boundary line 352. Additionally, the OES systems 390C, 390E can be configured to view opposing sides of diameter boundary line 353.

These measurements from the corresponding pairs can then be used to control the adjustments of the actuators 180A-180C. For example, a comparison between the measurements from OES systems 390A, 390F can be used to make adjustments with the actuator 180B. Similarly, a comparison between the measurements from OES systems 390B, 390D can be used to make adjustments with the actuator 180C. Additionally, a comparison between the measurements from OES systems 390C, 390E can be used to make adjustments with the actuator 180A.

As an example, if OES system 390B indicates an intensity for a wavelength peak of a given component (e.g., NH₃) is below the corresponding intensity measured by the OES system 390D when the intensity for that wavelength peak measured by OES system 390D is closer to an intensity setpoint for that component, then the actuator 180C can move the portions of the plate 155 and coils 170, 175 closest to the actuator 180C closer to the substrate support 118 (see FIG. 1A). This movement by the actuator 180C causes a tilt of the coils 170, 175 and a central axis of the coils 170, 175 (e.g., an axis substantially aligned in the Z-direction) to move towards the portion of the plasma measured by OES system 390B. This tilt in the axis of the coils 170, 175 increases the intensity of the magnetic field coupled into the portion of the processing volume 116 measured by OES system 390B, which in turn increases the intensity of the wavelength peak for the given component (i.e., NH₃) measured by the OES system 390B to result in more uniform intensity measurements by the OES systems 390B, 390D.

When viewed in a top view, each actuator 180A-180C can be described as being in a perpendicular radial arrangement relative to the orientations of the OES systems 390A-390F that are used to control that actuator. For example, a radius from the center 155C of the support plate 155 to the actuator 180C is perpendicular to the orientations 390B′, 390D′ of the OES systems 390B, 390D that are used to control the actuator 180C. Similarly, a radius from the center 155C of the support plate 155 to the actuator 180B is perpendicular to the orientations 390A′, 390F′ of the OES systems 390A, 390F that are used to control the actuator 180B. And similarly, a radius from the center 155C of the support plate 155 to the actuator 180A is perpendicular to the orientations 390C′, 390E′ of the OES systems 390C, 390E that are used to control the actuator 180A. This same perpendicular radial relationship applies to the processing system 300A described above. For example, for the processing system 300B, the actuator 180C is in a perpendicular radial relationship with the orientation 390B′ of the OES system 390B, the actuator 180B is in a perpendicular radial relationship with the orientation 390A′ of the OES system 390A, and the actuator 180A is in a perpendicular radial relationship with the orientation 390C′ of the OES system 390C.

Although the systems disclosed above are described as including three or six OES systems as well as three actuators (e.g., actuators 180A-180C) other processing systems may include more or fewer OES systems as well as more or fewer actuators. Furthermore, although the actuators 180A-180C are described as moving and/or tilting inductive coils for an ICP process based on feedback from the OES systems, similar actuators could also be used to adjust a position or tilt of other plasma generating components, such as a backing plate for a capacitively coupled plasma process. The backing plate could be moved (e.g., tilted) to modify a capacitively coupled plasma based on OES feedback using similar OES systems as the OES systems described herein. Other adjustments can also be made based on the OES measurements to obtain a more uniform plasma over a substrate, such as adjusting a flow of precursors to a portion of the processing volume for a process using a remote plasma source or adjusting a bias (e.g., a DC bias) provided to a portion of a substrate support. Furthermore, although examples were described above for adjusting the position of actuators based on OES measurements of a single wavelength peak, this was to provide a less complex example and during actual processes, the adjustment of the positions of the actuators can be based on data from multiple wavelength peaks, such as wavelength peaks from different components (e.g., different gases provided to the processing volume).

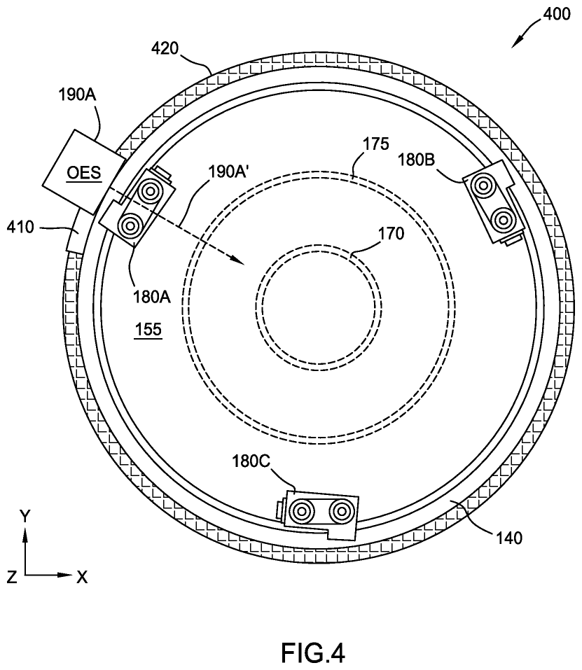

FIG. 4 is a top view of components in a processing system 400 for controlling an inductively coupled plasma in the process chamber 101, according to one embodiment. The processing system 400 is the same as the processing system 100 (see FIG. 1A) described above except that the processing system 400 includes only the OES system 190A, and the processing system 100 is configured to move the OES system 190A around the process chamber 101 and allow the OES system 190A to perform OES measurements at numerous locations around the process chamber 101. In some embodiments, the process chamber 101 can include a window (not shown) that extends for 360 degrees around the entire process chamber 101, so that OES system measurements can be taken from any location around the process chamber 101. The OES system 190A has the orientation 190A′ described above in reference to FIG. 1B, but the OES system used in the processing system 400 can have other orientations, such as the orientation 390A′ described above with reference to FIGS. 3A and 3B.

The processing system 400 includes an actuator 410 and a track 420 to move the OES system 190A around the process chamber 101. In some embodiments, the actuator 410 can stop moving the OES system 190A at various discrete locations, such as the locations for the three OES systems 190A, 190B, 190C shown in FIG. 1B. In other embodiments, many more locations can be used to perform OES measurements, such as ten or more locations, 100 or more locations, or even one thousand or more locations around the process chamber 101. In some embodiments, the actuator 410 can move the OES system 190A in a continuous or near continuous manner, and OES measurements can be performed during this movement. The processing system 400 can allow more OES measurements to be performed than the processing systems described above, so that a more detailed map of the spatial uniformity of the plasma can be obtained. With these additional measurements, different adjustments to the positions of actuators 180A-180C can be made to obtain a more uniform plasma during processing. Although the processing system 400 is shown with one OES system 190A, other embodiments can include two or more OES systems configured to move during a process. The use of additional OES systems configured to move can allow measurements of different portions of the plasma to be performed more quickly as well as additional measurements to be performed in some locations when compared to a processing system including only one movable OES system.

FIG. 5 is a process flow diagram of a method 1000 for generating a plasma in the process chamber 101 (see e.g., FIG. 1A) using any of the processing systems 100, 200, 300A, 300B, 400 described above, according to one embodiment. The controller 105 (see FIG. 1A) can execute a program stored in memory to perform the method 1000. The method begins at block 1002.

At block 1002, a substrate is positioned on the substrate support 118. However, for some processes, such as a plasma cleaning process, a substrate is not positioned in the process chamber during the method 1000.

At block 1004, the actuators 180A-180C are adjusted to be in initial positions for the process being performed in the process chamber 101. These initial positions can vary depending on the process being performed in the process chamber 101.

At block 1006, one or more gases are provided to the processing volume 116 of the process chamber 101. Also at block 1006, RF power is provided from the RF power sources 177, 178 to the coils 170, 175 to initiate the plasma in the processing volume 116 of the process chamber 101. In processes using a remote plasma source, the plasma is generated outside of the processing volume 116 and then provided to the processing volume 116.

At block 1008, OES measurements can be performed. The OES measurements can be performed by any of the OES systems described above in reference to FIGS. 1A-4. The OES measurements are performed on two or more different portions of the processing volume 116, so comparisons of the OES measurements between these different portions can be made. The OES measurements can be provided to the controller 105.

At block 1010, the controller 105 adjusts the position of one or more of the actuators 180A-180C based on the OES measurements provided at block 1008. These adjustments to the positions of the actuators can be made using any of the techniques described above in reference to FIGS. 1A-4. Overall, these adjustments can move, such as vertically move and/or tilt, the coils 170, 175 to improve the uniformity of a plasma generated in the processing volume of a process chamber. With this improved plasma uniformity, product uniformity and consistency can be improved. For a capacitively coupled plasma, a position and/or tilt of a backing plate connected to high frequency power (e.g., RF power) can be adjusted based on the OES measurements. In some embodiments, a bias (e.g., a DC bias) or RF power provided to different portions of a substrate support can be adjusted based on the OES measurements. In some embodiments, a flow of gas provided to a different portion (e.g., sectors 131-133) can be adjusted based on the OES measurements. While the plasma in the processing volume 116 is maintained, blocks 1008 and 1010 can continue to be executed until the process is complete.

The OES system measurements have largely been described as being used to for maintaining a single setpoint (e.g., an intensity setpoint for a single wavelength peak) during a process, but the OES measurements can also be used for other types of control schemes. For example, in some embodiments, it may be beneficial to reduce an offset between two, three, or more wavelength peaks (e.g., wavelength peaks from two, three, or more different gases, ions, and/or radicals) from corresponding setpoints to obtain a more spatially uniform plasma compared to using only one wavelength peak as described above in many of the examples. Furthermore, it may also be beneficial for one or more setpoints to change over time during a process. For example, it may be beneficial to use varying intensities for wavelength peaks during some processes. In one embodiment including a high aspect ratio structure, a deposition can start out using setpoints for wavelength peaks with higher intensities and then as the high aspect ratio feature is filled setpoints for wavelength peaks having lower intensities can be used or it may be beneficial to start with a lower setpoint and then switch to a higher setpoint. The controller 105 can adjust these setpoints during the process, and the OES system measurements can be used along with adjustments to the positions of the actuators to modify the plasma generated in the processing volume to achieve the varying intensity setpoints that change over time during the process. The OES system measurements can also be used to identify changes in a process. For example, the OES systems can be used to identify when an intensity of one or more wavelength peaks drops below a specified threshold. In one embodiment, a cleaning process is determined to be completed when intensities for one or more wavelength peaks drop below a specified threshold for a given amount of time (e.g., one minute).

While the OES systems described can be used for real-time control of processes being performed in processing chambers, data from the OES systems can also be used for other purposes. For example, the data from OES systems can be used to detect faults and to obtain consistent results within a given process chamber and across different process chambers. In one embodiment, a detection of a wavelength peak that does not normally occur during a given process can indicate a fault, such as a particular component should be replaced, the chamber should be cleaned, or there is an impurity in the gases provided to the chamber, among other potential faults. Once the reason for the abnormal wavelength peak is identified (e.g., chamber should be cleaned), then this abnormal wavelength peak can be a fault signature that the controller 105 can use to notify an operator that the chamber should be cleaned.

As another example, the OES systems may detect rapidly changing OES measurements, which could indicate problems with the equipment used to generate the plasma, such as the coils 170, 175. In some embodiments, data from the OES systems may be combined with other data to identify other fault signatures. For example, rapidly changing OES peaks coupled with measurements from one or more electrical sensors (e.g., voltage or current sensors) may be used to identify a particular fault, such as a problem with the matching circuit or a problem with an RF power source. As these faults reoccur over time, unique fault signatures that include OES measurements can be identified, so that the root cause of these faults is more quickly identified relative to before the OES measurements were used for these purposes.

The OES measurements can also be used for obtaining consistent results in different chambers for the same processes. For example, over time particular OES measurements (e.g., intensities for particular wavelength peaks of precursors provided for a process) may be identified that are more important than other OES measurements for obtaining consistent results in different process chambers. Then when a new chamber is being used to perform a particular process, the position of the actuators 180A-180C can be adjusted to reduce the difference between these particular OES measurements in the new chamber relative to the corresponding OES measurements from chambers already achieving consistent results for that particular process. The OES measurements can also be used to detect chamber drift over time. For example, over time it may be that the actuator positions previously used to perform processes are no longer achieving results within product specifications, and thus new actuator positions can be found to improve the process.

While the foregoing is directed to examples of the present disclosure, other and further examples of the disclosure may be devised without departing from the basic scope thereof, and the scope thereof is determined by the claims that follow.

What is claimed is:

1. A plasma processing system comprising:
a processing chamber comprising:
a chamber body enclosing a processing volume, the chamber body including one or more windows;
a substrate support in the processing volume;
a coil positioned over the substrate support; and
one or more actuators configured to move the coil;
one or more optical emission spectroscopy (OES) systems, each OES system optically coupled to one of the one or more windows and each OES system having an optical component configured to perform OES measurements on a portion of the processing volume; and
a controller configured to adjust a position of the one or more actuators to move the coil based on the OES measurements.

2. The plasma processing system of claim 1, wherein the one or more OES systems includes a first OES system and a second OES system.

3. The plasma processing system of claim 2, wherein the controller is configured to adjust the position of the one or more actuators to move the coil based on a comparison of a measurement from the first OES system with a measurement from the second OES system.

4. The plasma processing system of claim 2, wherein the optical component of the first OES system and the second OES system are each oriented towards a center of the substrate support.

5. The plasma processing system of claim 2, wherein the optical component of the first OES system and the second OES system each have an orientation that is offset from about ten degrees to about sixty degrees in a horizontal plane relative to a horizontal radii extending from a center of the substrate support to the corresponding optical component.

6. The plasma processing system of claim 2, wherein the optical component of the first OES system and the second OES system each have an orientation that is offset from about thirty degrees in a horizontal plane relative to a horizontal radii extending from a center of the substrate support to the corresponding optical component.

7. The plasma processing system of claim 1, wherein the one or more OES systems includes three OES systems positioned about 120 degrees apart from each other around the chamber body.

8. The plasma processing system of claim 7, wherein the one or more actuators includes three actuators, and each actuator has a same angular position relative to a center of the substrate support as one of the OES systems.

9. The plasma processing system of claim 1, wherein the one or more OES systems includes four or more OES systems, and each OES system is positioned 180 degrees relative to a center of the substrate support from another one of the one or more OES systems.

10. The plasma processing system of claim 1, wherein the one or more OES systems includes four or more OES systems, and the optical component of each OES system has an orientation that is parallel to an orientation of the optical component of another one of the one or more OES systems.

11. The plasma processing system of claim 1, further comprising an actuator coupled to a first OES system of the one or more OES systems, wherein the actuator coupled to the first OES system is configured to move the OES system to different locations around the chamber body.

12. The plasma processing system of claim 10, further comprising a track extending 360 degrees around the chamber body, wherein the actuator coupled to the first OES system is configured to move the first OES system around the entire track.

13. A method of performing a process in a process chamber, the method comprising:
positioning a substrate on a substrate support in a processing volume of a process chamber, the process chamber having a chamber body enclosing the processing volume;
providing one or more gases to the processing volume of the process chamber;
providing RF power to a coil disposed over the substrate support to generate a plasma of the one or more gases provided to the processing volume;
performing optical emission spectroscopy (OES) measurements of two or more locations of the processing volume during the generation of the plasma using one or more OES systems, each OES system having an optical component configured to view a portion of the processing volume; and
moving the coil during the generation of the plasma based on the OES measurements.

14. The method of claim 13, wherein the one or more OES systems includes a first OES system and a second OES system.

15. The method of claim 14, moving the coil during the generation of the plasma is based on a comparison of a measurement from the first OES system with a measurement from the second OES system.

16. The method of claim 13, wherein the coil is moved in a direction to reduce a difference between an intensity for a wavelength peak measured by a first OES system of the one or more OES systems relative to a setpoint for the intensity of that wavelength peak.

17. The method of claim 13, wherein the one or more OES systems includes three OES systems, wherein each OES system is positioned about 120 degrees apart from the other OES systems.

18. The method of claim 13, wherein the one or more OES systems includes four or more OES systems, and each OES system is positioned 180 degrees relative to a center of the substrate support from another one of the one or more OES systems.

19. The method of claim 13, wherein the one or more OES systems includes four or more OES systems, and the optical component of each OES system has an orientation that is parallel to the optical component of another one of the one or more OES systems.

20. A method of performing a process in a process chamber, the method comprising:
performing optical emission spectroscopy (OES) measurements of a plasma in a processing volume of a process chamber using four or more OES systems, each OES system having an optical component configured to view a portion of the processing volume, wherein the optical component of each OES system has an orientation that is offset from about ten degrees to about sixty degrees in a horizontal plane relative to a horizontal radii extending from a center of a substrate support in the processing volume to the corresponding optical component; and
adjusting an output to modify a spatial uniformity of the plasma based on the OES measurements.
